(19) United States
(12) Patent Application Publication
(10) Pub. No.: US 2015/0275359 A1
(43) Pub. Date: Oct. 1, 2015

(54) Substrate Processing Apparatus

(71) Applicant: TOKYO ELECTRON LIMITED, Tokyo (JP)

(72) Inventors: Kohei FUKUSHIMA, Oshu-shi (JP); Tetsushi OZAKI, Nirasaki (JP)

(21) Appl. No.: 14/672,558

(22) Filed: Mar. 30, 2015

(30) Foreign Application Priority Data
Mar. 31, 2014 (JP) 2014073737

(51) Int. Cl. C23C 16/458; C23C 16/52; C23C 16/50; C23C 16/44; C23C 16/455

(52) U.S. Cl. CPC C23C 16/458; C23C 16/4412; C23C 16/455; C23C 16/50; C23C 16/52

(57) ABSTRACT

The present disclosure provides a substrate processing apparatus for supplying a process gas to substrates to perform a process thereon. The apparatus comprises: an electrode installed to extend in a length direction of the substrate holding unit to activate the process gas by supplying power to the process gas; a structure installed in the reaction chamber to extend in the length direction of the substrate holding unit in a height region where the substrates are arranged; and an exhaust opening configured to vacuum exhaust an interior of the reaction chamber. The structure is disposed in a region spaced apart from a portion of the electrode closest to the structure by equal to or more than 40 degrees in the left or right direction about a central portion of the reaction chamber when the reaction chamber is viewed from top.

### CROSS-REFERENCE TO RELATED APPLICATION

This application claims the benefit of Japanese Patent Application No. 2014-073737, filed on Mar. 31, 2014, in the Japan Patent Office, the disclosure of which is incorporated herein in its entirety by reference.

### TECHNICAL FIELD

The present disclosure relates to a substrate processing apparatus for supplying a process gas to substrates held in a substrate holding unit in a shape of a shelf in a vertical reaction chamber having a vacuum atmosphere, thereby processing the substrates.

### BACKGROUND

It has been known that a process is performed on semiconductor wafers (hereinafter, referred to as “wafers”) held in a wafer boat in the shape of a shelf, using a process gas activated by plasma, in a reaction chamber of a vertical heat treatment apparatus. For example, it is disclosed a method of alternately supplying a source gas and a reaction gas, which reacts with the source gas to form a reaction product, to a wafer so that the reaction gas is activated to promote reaction with the source, when a SiO₂ film is formed using a so-called ALD (Atomic Layer Deposition) process.

Meanwhile, since in many cases, dummy wafers are mounted at upper and lower portions of the wafer boat, a plurality of batch processes are performed with the dummy wafers mounted. A thin film is accumulated on the dummy wafer, and, if the thickness of the accumulated thin film is not less than a predetermined thickness, cleaning of the reaction chamber is performed. However, the present inventors doubted that the dummy wafer and the plasma were related to each other to be factors causing particles in that the particles in the reaction chamber were scattered and then attached to the wafers before a scheduled cleaning time.

There is proposed a technique of performing an oxidation purge process with the objects to be processed unloaded from the processing chamber, thereby reducing the discharge amount of an Si source gas in a film deposited on the inner wall of the processing chamber. However, this technique is to prevent the particles being produced by a reaction between the Si source gas and an oxidizing species. There is also proposed a technique of switching a hot side and a ground side of electrodes for generating plasma and applying high frequency power thereto. However, in this technique, the deposition of an extraneous matter to the hot side of the electrodes is reduced, thereby reducing cleaning frequency. Therefore, the problem of the present disclosure cannot be solved even using the above described techniques.

### SUMMARY

The present invention has been made in consideration of the above circumstances, and some embodiments of the present disclosure provide a technique for reducing particles attached to substrates when a process gas is used to process the substrates held in the shape of a shelf in a substrate holding unit in a vertical reaction chamber.

According to one embodiment of the present disclosure, there is provided a substrate processing apparatus for supplying a process gas to a plurality of substrates to perform a process on the plurality of substrates, which are semiconductor wafers having a diameter of 300 mm or more held in a substrate holding unit in a shape of a shelf in a vertical reaction chamber having a vacuum atmosphere. The apparatus includes: an electrode installed to extend in a length direction of the substrate holding unit to activate the process gas by supplying a power to the process gas; a structure installed in the reaction chamber to extend in the length direction of the substrate holding unit in a height region where the plurality of substrates are arranged; and an exhaust opening configured to vacuum exhaust an interior of the reaction chamber. The structure is disposed in a region spaced apart from a portion of the electrode closest to the structure by equal to or more than 40 degrees in a left or right direction about a central portion of the reaction chamber when the reaction chamber is viewed from top.

According to another embodiment of the present disclosure, there is provides a substrate processing apparatus for supplying a process gas to a plurality of substrates to perform a process on the plurality of substrates, which are held in a substrate holding unit in the shape of a shelf in a vertical reaction chamber having a vacuum atmosphere. The apparatus comprising: an electrode installed to extend in a length direction of the substrate holding unit to activate the process gas by supplying a power to the process gas; a structure installed in the reaction chamber to extend in the length direction of the substrate holding unit in a height region where the plurality of substrates are arranged; and an exhaust opening configured to vacuum exhaust an interior of the reaction chamber. The structure is disposed in a region having an electric field intensity of less than 8.12×10² V/m based on the power supplied to the electrode.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a transverse sectional view showing an example of a substrate processing apparatus according to the present disclosure.

FIG. 2 is a longitudinal sectional view showing an example of the substrate processing apparatus.

FIG. 3 is a longitudinal sectional view showing an example of the substrate processing apparatus.

FIG. 4 is a transverse sectional view showing an example of the substrate processing apparatus.

FIG. 5 is a transverse sectional view showing an example of the substrate processing apparatus.

FIGS. 6A and 6B are simulation views of electric field vectors.

FIG. 7A and 7B are simulation views of an electric field intensity distribution.

FIG. 8 is a characteristic diagram showing a Paschen curve.

FIG. 9 is a characteristic diagram showing a result of an evaluation test.

FIG. 10 is a characteristic diagram showing a result of the evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

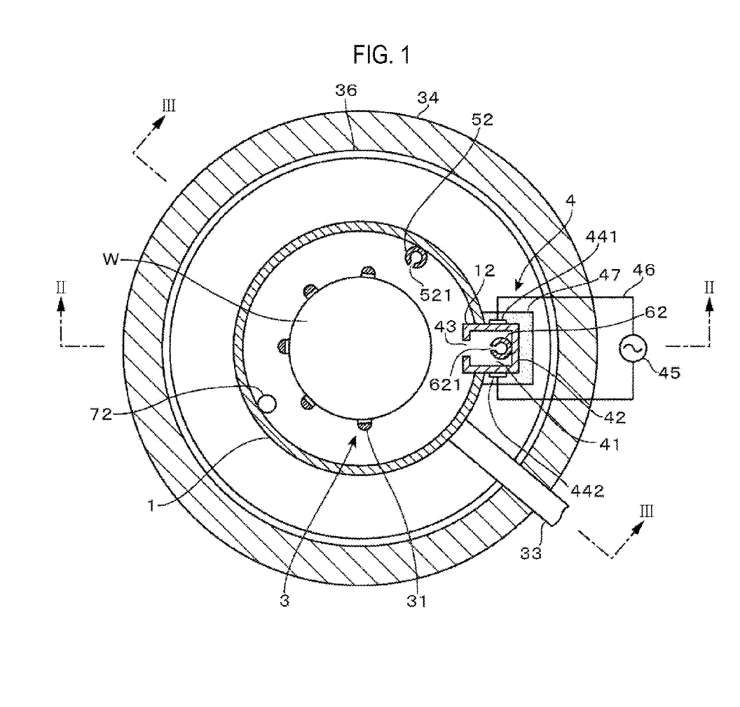

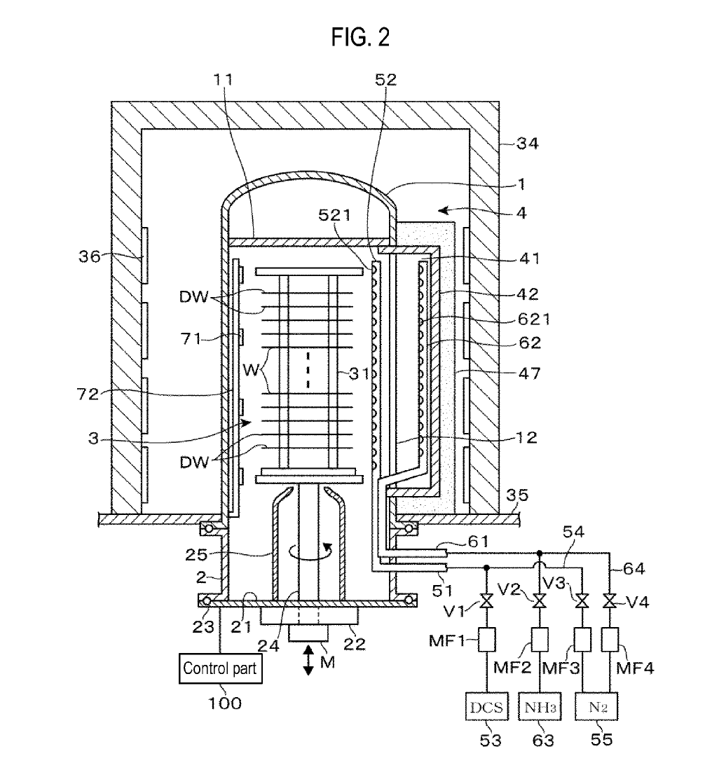

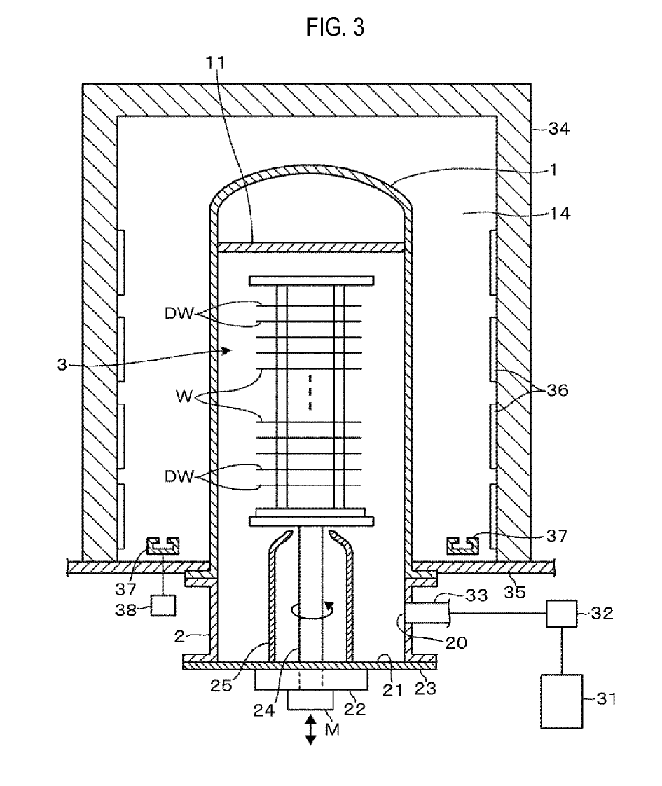

A substrate processing apparatus according to a first embodiment of the present disclosure will be described with reference to FIGS. 1 to 5. FIG. 1 is a transverse sectional view of a substrate processing apparatus, FIG. 2 is a longitudinal sectional view of the substrate processing apparatus taken along line II-II of FIG. 1, and FIG. 3 is a longitudinal sectional view of the substrate processing apparatus taken along line III-III of FIG. 1. In FIGS. 1 to 5, reference numeral 1 designates a reaction chamber formed, for example, of quartz, in the shape of a vertical cylinder, and an upper portion in the reaction chamber 1 is sealed with a ceiling plate 11 made of quartz. A manifold 2 formed, for example, of stainless steel, in the shape of a cylinder, is connected to a lower end of the reaction chamber 1. A lower end of the manifold 2 is open as a substrate loading/unloading opening 21 and is configured to be airtightly closed by a lid 23 made of quartz installed to a boat elevator 22. A rotating shaft 24 is installed at a central portion of the lid 23 to pass through the lid 23, and a wafer boat, which is a substrate holding unit, is mounted on the upper end of the rotating shaft 24.

The wafer boat 3 is configured to have, for example, five posts 31, to support outer circumferential portions of wafers W, and to hold a plurality of wafers W, for example, 111 sheets of wafers W in the shape of a shelf. The wafer W has a diameter of 300 mm or more, and dummy wafers DW are mounted at an upper portion (e.g., three sheets of wafers from the uppermost wafer) and a lower portion (e.g., three sheets of wafers from the lowermost wafer) in a wafer arrangement region of the wafer boat 3. In FIG. 2, among the wafers in the wafer boat 3, two sheets of wafers at the upper portion and two sheets of wafers at the lower portion are the dummy wafers DW. The boat elevator 22 is configured to be lifted up and down by a lifting mechanism, and the rotating shaft 24 is configured to be freely rotated around a vertical axis by a motor M constituting a driving part. In these figures, reference numeral 25 designates a heat insulating unit. Accordingly, the wafer boat 3 is configured be lifted up and down between a processing position, at which the wafer boat 3 is loaded (carried) into the reaction chamber 1 and the substrate loading/unloading opening 21 of the reaction chamber 1 is blocked by the lid 23, and an unloading position at which the wafer boat 3 is under the reaction chamber 1.

As shown in FIGS. 1 and 2, a plasma generating part 4 is installed at a portion of the sidewall of the reaction chamber 1. The plasma generating part 4 is provided with a plasma generating chamber having a generally quadrangular cross section, which is formed to cover a vertically long and narrow opening 12 formed in the sidewall of the reaction chamber 1. The plasma generating chamber 41 is a space which is surrounded by a wall portion expanding outward along the length direction of the wafer boat 3 at a portion of the sidewall of the reaction chamber 1, and is configured, for example, by airtightly bonding a partition wall 42, for example, made of quartz, to the sidewall of the reaction chamber 1. As shown in FIG. 1, a portion of the partition wall 42 enters into the reaction chamber 1, and a long and narrow gas supply opening 43 for allowing gas to pass therethrough is formed in a front face of the partition wall 42 within the reaction chamber 1. As described above, the one end portion of the plasma generating chamber 41 is open in the reaction chamber 1 to communicate each other. The opening 12 and the gas supply opening 43, for example, are formed vertically long to cover all the wafers W supported in the wafer boat 3.

A pair of opposing electrodes 441 and 442 for generating plasma are respectively installed on outer surfaces of both sidewalls of the partition wall 42 along the length direction of the wafer boat 3 to extend in its length direction (up and down direction). The electrodes 441 and 442 are to generate capacitively coupled plasma. When the reaction chamber 1 is viewed from the plasma generating chamber 41, the electrode positioned at the right side is the first electrode 441 and the electrode positioned at the left side is the second electrode 442. A high frequency power source 45 for generating plasma is connected to the first and second electrodes 441 and 442 through feed lines 46, so that the electrodes 441 and 442 are supplied with a high frequency voltage, for example, at 13.56 MHz and at a power ranged from not less than 30 W to not more than 200 W, e.g., 150 W, thereby generating plasma. An insulating protective cover 47, for example, made of quartz, is installed outside the partition wall 42 to cover the partition wall 42.

A cylindrical heat insulating body 34 is fixedly installed on a base body 35 to surround the circumference of the reaction chamber 1, and a cylindrical heater 36 configured as a resistance heating element is installed on the inside of the heat insulating body 34. The heater 36 is vertically divided into a plurality of stages and installed on the inner wall of the heat insulating body 34. As shown in FIG. 3, a ring-shaped gas supply port 37 is installed, for example, between the reaction chamber 1 and the heater 36, and configured for a coolant gas to be supplied from a coolant gas supply part 38 to the gas supply port 37. In FIG. 2, the gas supply port 37 is not shown.

A source gas supply channel 51 for supplying a silane-based gas that is a source gas, e.g., dichlorosilane (DCS: SiH₂Cl₂), passes through the sidewall of the manifold 2, and a source gas nozzle 52 is installed at the leading end of the source gas supply channel 51. The source gas nozzle 52 is made, for example, of a quartz pipe having a circular cross section. As shown in FIG. 2, the source gas nozzle 52 is vertically installed alongside the wafer boat 3 in the reaction chamber 1 so as to extend along the arrangement direction of the wafers W held in the wafer boat 3. The source gas nozzle 52 is disposed in the vicinity of the wafer boat 3, so that the distance between the outer surface of the source gas nozzle 52 and the outer circumference of the wafers W in the wafer boat 3 is, for example, 35 mm. The external diameter of the source gas nozzle 52 is, for example, 25 mm.

A reaction gas supply channel 61 for supplying ammonia (NH₃) gas that is a reaction gas passes through the sidewall of the manifold 2, and a reaction gas nozzle 62, for example, made of quartz, is installed at the leading end of the reaction gas supply channel 61. The reaction gas is a gas that reacts with molecules of the source gas to produce a reaction product, and corresponds to a process gas in the present disclosure. The reaction gas nozzle 62 extends upward in the reaction chamber 1 and then bends in its middle to be disposed in the plasma generating chamber 41.

A plurality of gas ejection holes 521 and 621 for respectively ejecting the source gas and the reaction gas are formed in the source gas nozzle 52 and the reaction gas nozzle 62. The gas ejection holes 521 or 621 are formed to be spaced apart from each other at a predetermined distance along the length direction of the nozzle 52 or 62, to eject gas to gaps between vertically adjacent wafers W held in the wafer boat 3.

The source gas supply channel 51 is connected to the supply source 53 of the dichlorosilane that is the source gas through a valve V1 and a flow rate adjusting part MF1. In addition, the source gas supply channel 51 is connected to a supply source 55 of nitrogen gas that is a replacement gas through a valve V3 and a flow rate adjusting part MF3 by a branch channel 54 branching at a downstream side of the valve V1. The reaction gas supply channel 61 is connected to the supply source 63 of the ammonia gas that is the reaction gas through a valve V2 and a flow rate adjusting part MF2. In addition, the reaction gas supply channel 61 is connected to the supply source 55 of the nitrogen gas through a valve V4 and a flow rate adjusting part MF4. The valve supplies the gas or cuts off the gas supply, and the flow rate adjusting part adjusts the supply amount of the gas. The later-described valves and flow rate adjusting parts respectively have the same functions.

As shown in FIG. 3, an exhaust opening 20 for vacuum exhausting the interior of the reaction chamber 1 is formed in the sidewall of the manifold 2. The exhaust opening 20 is connected to a vacuum pump 39 constituting a vacuum exhaust unit through an exhaust channel 33 having a pressure adjusting part 32. Accordingly, the process pressure in the reaction chamber 1 is set to not less than 133 Pa (1 Torr), more preferably, not less than 6.65 Pa (0.05 Torr) and not more than 66.5 Pa (0.5 Torr). A thermocouple 71 constituting a temperature detecting part is installed inside the reaction chamber 1. For example, a plurality of thermocouples 71 is prepared to respectively detect temperatures of a heat treatment atmosphere which is subjected to the heater 36 divided into the plurality of stages. The plurality of thermocouples 71, for example, is vertically installed inside a common quartz pipe 72 installed onto the inner wall of the reaction chamber 1. The quartz pipe 72, for example, is installed alongside the wafer boat 3 to extend along the arrangement direction of the wafers W.

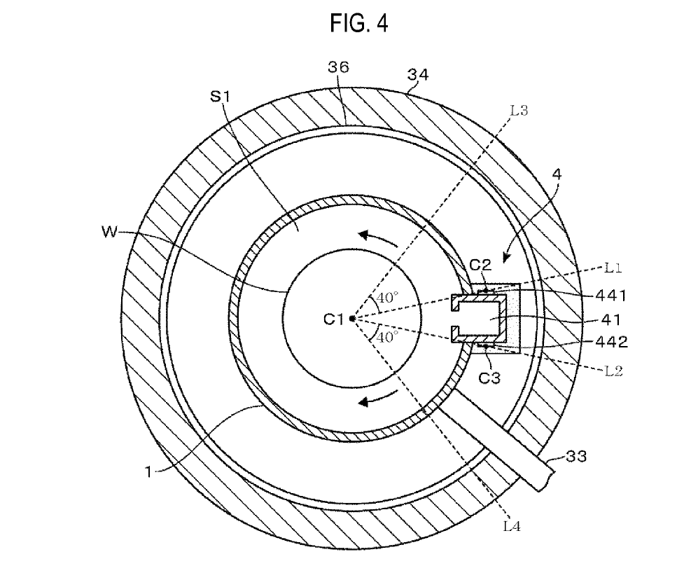

The source gas nozzle 52 and the quartz pipe 72 having the thermocouple 71 correspond to structures of the present disclosure. Each of these structures is disposed in a region for preventing the abnormal electric discharge from being generated between the structures and the dummy wafers DW. In other words, when the wafer has a diameter of not less than 300 mm, a region spaced apart in the left or right direction from a portion of the electrode 441 or 422 closest to the structure by not less than 40 degrees about the central portion of the reaction chamber 1 when the reaction chamber 1 is viewed from top. Specifically, it will be described with reference to FIG. 4. The central portion of the reaction chamber 1 corresponds to a central portion C1 of the wafers W mounted in the wafer boat 3, and the portions of the electrodes 441 and 442 closest to the structures respectively correspond to a central portion C2 of an outer surface of the first electrode 441 and a central portion C3 of an outer surface of the second electrode 442.

Assuming that the line connecting the central portion C1 of the wafer and the central portion C2 of the first electrode 441 is designated as a first line L1 and the line connecting the central portion C1 of the wafer and the central portion C3 of the second electrode 442 is designated as a second line L2, the structure is disposed in a region spaced apart from the first line L1 by not less than 40 degrees in the left or right direction, and a region spaced apart from the second line L2 by not less than 40 degrees in the left or right direction. In this example, since the plasma generating chamber 41 is installed in the left direction of the first electrode 441 and the right direction of the second electrode 442, the structure is disposed in a first region S1 between a line L3 spaced apart from the first line L1 by 40 degrees in the right direction and a line L4 spaced apart from the second line L2 by 40 degrees in the left direction.

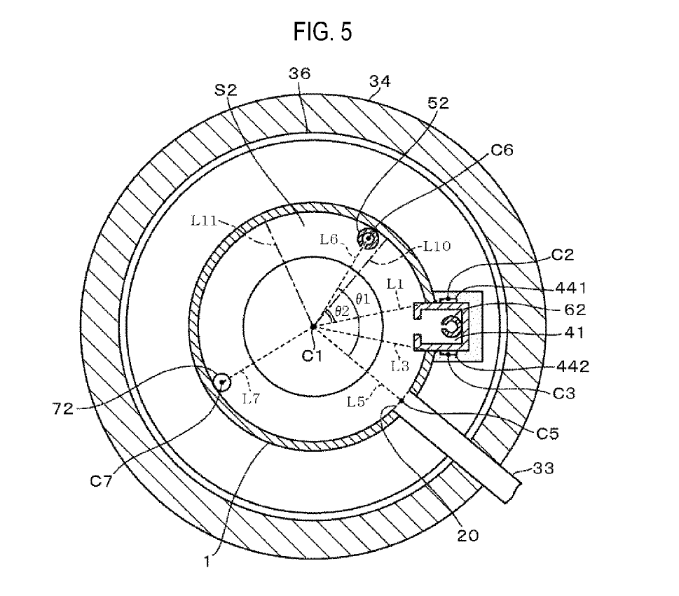

In order to prevent the gas flow from being disturbed, the position of the source gas nozzle 52 is preferably installed at a position having an open angle ranged from not less than 90 degrees to not more than 160 degrees from a central portion C5 in the left/right direction of the exhaust opening 20 about the central portion of the reaction chamber 1 (the central portion C1 of the wafer) when the reaction chamber 1 is viewed from top, as shown in FIG. 5. Practically, although the exhaust opening 20 is provided in the sidewall of the manifold 2 as shown in FIG. 3, for convenience of illustration, FIG. 5 shows that a portion in the circumferential direction of the sidewall of the reaction chamber 1 is configured as the exhaust opening 20.

In this example, since the source gas nozzle 52 is installed at a position moved in the right direction (counterclockwise direction) from the exhaust opening 20, the source gas nozzle 52 is preferably disposed in a region where a counterclockwise angle θ1 (in the right direction) from the central portion C5 of the exhaust opening 20 is ranged from not less than 90 degrees to not more than 160 degrees. The angle θ1 is an angle made by a line L5 connecting the central portion C1 of the wafer and the central portion C5 of the exhaust opening 20 and a line L6 connecting a central portion C6 of the source gas nozzle 52 and the central portion C1 of the wafer. The disposition region set by a relationship with the exhaust opening 20 as described above is referred to as a second region S2. The second region S2 is a region between L10 and L11 respectively indicated by one-dot chain lines in FIG. 5.

The reason that the range is preferable will be described. If the angle θ1 is smaller than 90 degrees, the source gas nozzle 52 approaches the exhaust opening 20. Hence, the ejection direction of gas from the source gas nozzle 52 and the exhaust direction of gas from the exhaust opening 20 are not aligned, and the gas flow is disturbed. Therefore, it is apprehended that in-plane and inter-plane uniformities of film thickness may be deteriorated. If the angle θ1 is greater than 160 degrees, the gas flow from the source gas nozzle 52 collides with the gas flow generated by the disposition of the exhaust opening 20 and the reaction gas nozzle 62. Therefore, it is apprehended that the flow velocity of gas may be lowered, and the film forming performance may be deteriorated.

Continuously, the reason that the structure is disposed in the first region S1 will be described in detail. The present inventors speculate that, in an electric field distribution generated by the electrodes 441 and 442, if the structure is disposed in a region having a strong electric field, particles attached to the wafer W increase even though the thickness of a thin film stacked on the dummy wafer DW is small. Based on this, the mechanism of the production of particles is understood as follows. As described later, the dummy wafer DW is in a state in which they are mounted in the wafer boat 3 during a plurality of batch processes, and therefore, the thickness of the dummy wafer DW gradually increases. If the structure is disposed in a region having a strong electric field, the electric field skips over the dummy wafer DW through the structure, and therefore, the abnormal electric discharge is generated between the structure and the dummy wafer DW. The abnormal electric discharge is unstable, such as on/off of the state of plasma being frequently switched. If the abnormal electric discharge occurs, strong damage is locally applied to a film near the periphery of the dummy wafer DW, so that the film is partially exfoliated and scattered, and the exfoliated and scattered matter as particles may be attached to the wafer W. For this reason, it is necessary to dispose the structure in a region having an electric field intensity small to an extent where the generation of the abnormal electric discharge is prevented.

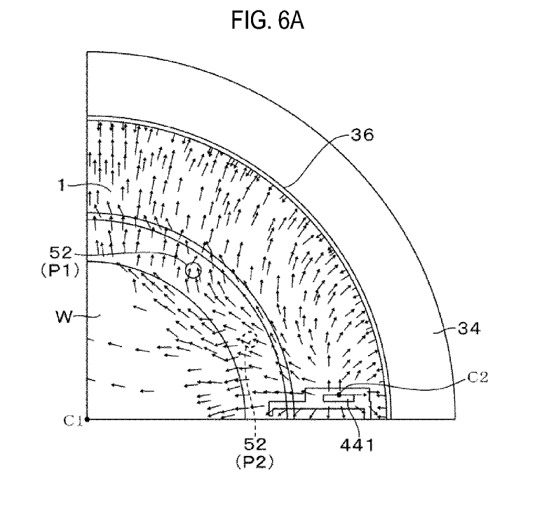

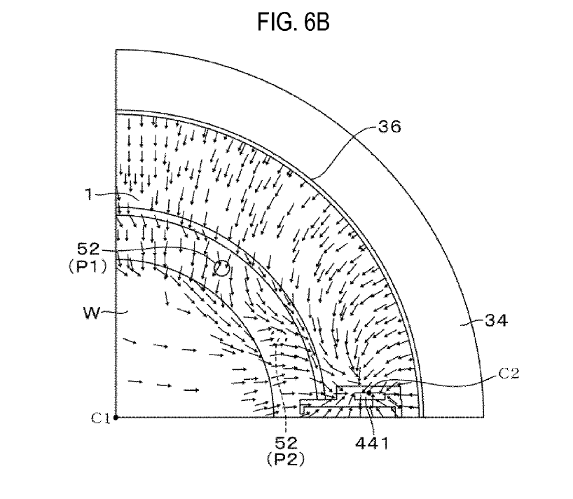

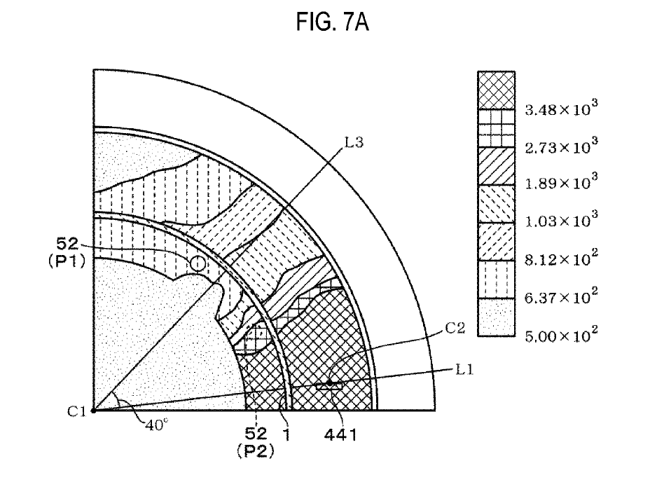

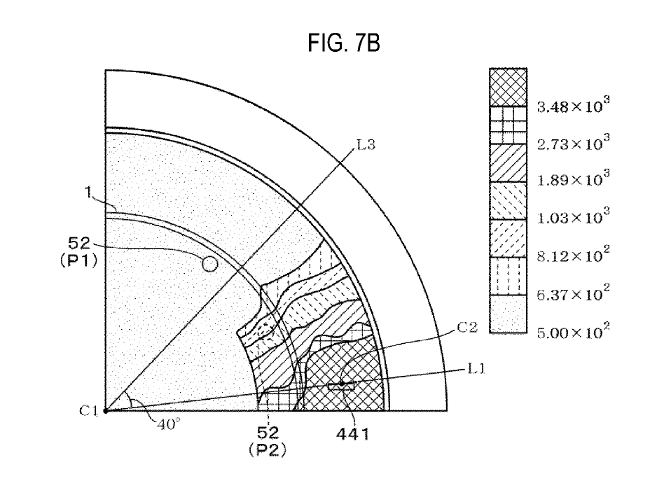

FIGS. 6A, 6B, 7A and 7B show results of electrostatic field simulations, obtained from Ansoft Corp., “Maxwell SV”. FIG. 6A shows electric field vectors when a voltage of +500 V more than an actual measurement value when plasma is generated at a power of 150 W, is applied to the first electrode 441 and FIG. 6B shows electric field vectors when a voltage of −500 V less than said actual measurement value is applied to the first electrode 441. FIG. 7A shows an electric field intensity distribution when the voltage of +500 V is applied to the electrode 441, and FIG. 7B shows an electric field intensity distribution when the voltage of −500 V is applied to the electrode 441. In the simulations, the diameter of the wafer W was set to 300 mm, the diameter of the reaction chamber 1 was 400 mm, the cross-sectional size of the electrode 441 was set to 15 mm×2 mm, and the linear distance between the central portion C1 of the reaction chamber 1 (the central portion C1 of the wafer) and the central portion C2 of the electrode 441 was set to 425 mm.

In FIGS. 6A, 6B, 7A and 7B, when a film forming process described later is performed by disposing the source gas nozzle 52 at a position P1 indicated by a solid line, the quantity of particles attached to the wafer W is small. When the source gas nozzle 52 is disposed at a position P2 indicated by a dotted line, the quantity of the particles is large. It was also confirmed that if the power applied to the electrodes 441 and 442 is reduced even when the source gas nozzle 52 is disposed at the position P2, the quantity of the particles is decreased.

From this point of view, it is inferred that when the source gas nozzle 52 is disposed at the position P1, the generation of the abnormal electric discharge between the dummy wafer DW and the electrodes 441 and 442 is prevented, but when the source gas nozzle 52 is disposed at the position P2, the abnormal electric discharge is generated. In addition, it can be supposed that whether or not the abnormal electric discharge is generated, is determined according to an electric field intensity of the region in which the source gas nozzle 52 is placed.

Here, an electric field intensity distribution will be described. The electric field intensity increases as it comes closer to the electrode 441. The electric field decreases as it is spaced apart from the electrode 441. Therefore, the electric field intensity at the position P1 distant from the electrode 441 is smaller than the electric field intensity at the position P2 close to the electrode 441. Specifically, when the voltage of +500 V is applied to the first electrode 441, the electric field intensity at the position P1 is greater than 6.37×10² V/m and smaller than 8.12×10² V/m. In addition, when the voltage of −500 V is applied to the electrode 441, the electric field intensity at the position P1 is greater than 5.00×10² V/m and smaller than 6.37×10² V/m.

When the voltage of +500 V is applied to the first electrode 441, the electric field intensity at the position P2 is greater than 1.89×10³ V/m and smaller than 3.48×10³ V/m. When the voltage of −500 V is applied to the electrode 441, the electric field intensity at the position P2 is greater than 8.12×10² V/m and smaller than 1.89×10³ V/m.

It is understood that since the electric field intensity of the position P1 is smaller than 8.12×10² V/m as described above, if the source gas nozzle 52 (the structure) is disposed in a region having an electric field intensity of less than 8.12×10² V/m, the abnormal electric discharge can be prevented from being generated. Referring to FIGS. 7A and 7B, it is apparent that the region (first region S1) spaced apart in the left or right direction from the portion of the electrode 441 or 422 closest to the structure by not less than 40 degrees about the central portion C1 of the reaction chamber 1 is a region having an electric field intensity of less than 8.12×10² V/m. Thus, if the source gas nozzle 52 (the structure) is disposed in the first region S1, the abnormal electric discharge is prevented from being generated and thus the generation of the particles can be reduced. The disposition of the structure in the first region S1 refers to disposing the structure so that the whole of the structure is accommodated in the first region as viewed from top.

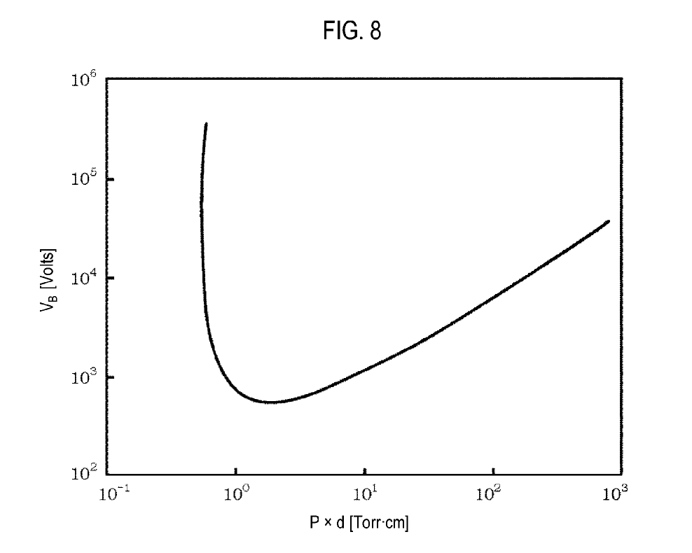

The prevention of the abnormal electric discharge by disposing the structure in the first region S1 can be intuitively understood by Paschen's Law. The Paschen's Law shows that a voltage VB at which electric discharge is generated between parallel electrodes, as shown in the following Formula (1), is represented as a function of multiplication of a gas pressure P and a distance d between the electrodes. The function represents a Paschen curve shown in FIG. 8.

VB=f(P×d) (1)

In FIG. 8, the horizontal axis represents (P×d), the vertical axis represents a voltage VB at which the electric discharge is generated, and data of the nitrogen gas are shown.

As shown in FIG. 8, the electric discharge voltage VB has a minimum value, which means that plasma is easily generated in the vicinity of the minimum value. If the pressure in the reaction chamber 1 is set to P (Torr), and the linear distance between the structure and the electrode close to the structure is set to d (cm), the present inventors intend that the structure is disposed in a region deviated to the right side from minimum value, i.e., a region having a large distance d, thereby preventing the abnormal electric discharge from being generated.

In the viewpoint of reducing the production of particles by preventing the abnormal electric discharge from being generated as described above, the structure in the reaction chamber 1 is preferably disposed in the first region S1. For example, in consideration of preventing the gas flow from being disturbed or the deterioration of film forming performance, the structure in the reaction chamber 1 is more preferably disposed in the range where the first and second regions S1 and S2 overlap each other. Accordingly, the structure is preferably disposed in the region when the pressure of the reaction chamber 1 is not more than 133 Pa (1 Torr), more preferably, not less than 6.65 Pa (0.05 Torr) and not more than 66.5 Pa (0.5 Torr), and the diameter of the wafer W is 300 mm. More preferably, the quartz pipe 72 is disposed in the first region S1, and the source gas nozzle 52 is disposed in a region where an angle θ2 (see FIG. 5) made by the central portion C2 of the first electrode 441 and the central portion C6 of the source gas nozzle 52 when viewed from the central portion C1 of the wafer is ranged from not less than 40 degrees to not more than 110 degrees.

In this example, the exhaust opening 20 is provided, for example, at a position of 45 degrees (the angle made by the lines L1 and L5) from the first electrode 441 in the left direction, and the source gas nozzle 52 is disposed, for example, at a position of 50 degrees (angle θ2 made by the lines L1 and L6) from the first electrode 441 in the right direction.

Also, the quartz pipe 72 having the thermocouple 71 is disposed, for example, at a position of 140 degrees (angle made by the line L3 and a line L7 connecting a central portion C7 of the quartz pipe 72 and the central portion C1 of the wafer) from the closest second electrode 442. Since the thermocouple 71 is installed onto the quartz pipe 72, if the quartz pipe 72 is disposed in the first region S1, the thermocouple 71 is also disposed in the first region S1.

The substrate processing apparatus configured as described above, as shown in FIG. 1, is connected to a control part 100. The control part 100 may includes, for example, a computer having a CPU (not shown) and a memory part (not shown), and the memory part stores a program that incorporates a step (command) group related to the operation of the film processing apparatus, e.g., in this example, the control when the film forming process is performed on the wafers W in the reaction chamber 1. The program may be stored in, for example, a recording medium such as a hard disc, a compact disc, a magneto-optical disc, or a memory card, and installed in the computer from the recording medium.

Continuously, the operation of the substrate processing apparatus of the present disclosure will be described. First, the wafer boat 3 having unprocessed wafers W mounted therein is carried (loaded) into the reaction chamber 1, and the interior of the reaction chamber 1 is set to a vacuum atmosphere of about 26.55 Pa (0.2 Torr) by the vacuum pump 39. The wafers W are heated to a predetermined temperature, e.g., 500 degrees C., by the heater 36. In a state in which the wafer boat 3 is rotated, the valves V1, V3 and V4 are opened, and the valve V2 is closed, so that dichlorosilane gas and nitrogen gas at a predetermined flow rate are supplied into the reaction chamber 1 through the source gas nozzle 52, and the nitrogen gas is supplied into the reaction chamber 1 through the reaction gas nozzle 62.

Since the interior of the reaction chamber 1 is set to the vacuum atmosphere, the dichlorosilane gas ejected from the source gas nozzle 52 flows out toward the exhaust opening 20 in the reaction chamber 1 and is discharged to the outside through the exhaust channel 33. Since the wafer boat 3 rotates, the dichlorosilane gas reaches the entire surface of the wafer, so that molecules of the dichlorosilane gas are adsorbed onto the surface of the wafer. Thereafter, the valves V1 and V2 are closed, and the valves V3 and V4 are opened, thereby stopping the supply of the dichlorosilane gas. In the meantime, the nitrogen gas that is a replacement gas is supplied from the source gas nozzle 52 and the reaction gas nozzle 62 into the reaction chamber 1 for a predetermined time, so that the dichlorosilane gas in the reaction chamber 1 is replaced by the nitrogen gas. Subsequently, a power of 100 W, for example, is supplied to the high frequency power source 45. In addition, the valve V1 is closed, and the valves V2, V3 and V4 are opened, so that ammonia gas that is a reaction gas and the nitrogen gas are supplied into the reaction chamber 1 through the reaction gas nozzle 62.

Accordingly, plasma is generated in the plasma generating chamber 41, so that active species, such as N radicals, H radicals, NH radicals, NH₂ radicals, and NH₃ radicals, are generated. The active species are adsorbed onto the surface of the wafer W. The molecules of the dichlorosilane gas react with the active species of NH₃ on the surface of the wafer W, thereby forming a thin silicon nitride film (SiN film). After the supply of the ammonia gas is performed as described above, the high frequency power source 45 is turned off, the valves V1 and V2 are closed, and the valves V3 and V4 are opened. Then, the nitrogen gas is supplied from the source gas nozzle 52 and the reaction gas nozzle 62 into the reaction chamber 1, so that the ammonia gas in the reaction chamber 1 is replaced by the nitrogen gas. By repeating such a series of processes, the thin SiN films are laminated layer by layer on the surface of the wafer W, so that an SiN film having a desired thickness is formed on the surface of the wafer W.

After the film forming process is performed as described above, the nitrogen gas is supplied into the reaction chamber 1 by opening, for example, the valves V3 and V4, so that the interior of the reaction chamber 1 is returned to atmospheric pressure. Thereafter, the wafer boat 3 is carried out (unloaded), the wafers W where the film forming process is terminated are taken out from the wafer boat 3, and unprocessed wafers W are mounted in the wafer boat 3. A next batch process starts in a state in which dummy wafers DW are mounted as they are. The batch process is repeated plural times in the state in which the dummy wafers DW are mounted as described above.

According to the embodiment described above, since the structure installed in the reaction chamber 1 is disposed in a region in which the electric field intensity formed by the electrodes 441 and 442 is small, which is the first region S1, the generation of unstable and abnormal electric discharge is prevented between the structure and the dummy wafers DW, as described above. Thus, the production of particles resulting from the abnormal electric discharge is prevented, thereby reducing the particles. Although the production of particles can be prevented by reducing the power applied to the high frequency power source 45, if the power is reduced, the film forming performance such as the quality of a film or the loading effect is deteriorated, which is not a satisfactory method. According to the present disclosure, since the particles are reduced in a simple manner that the structure is disposed in the appropriate region S1 or S2, it is unnecessary to remarkably modify the configuration of the apparatus, which is effective.

The wafer boat 3 is disposed at a position somewhat close to the electrodes 441 and 442, but as shown in the electric field intensity distribution of FIGS. 7A and 7B, the region having the wafer boat 3 disposed therein is a region having an electric field intensity of less than 6.37×10² V/m. For this reason, when power is applied to the electrodes 441 and 442, an electric field skips over the dummy wafers DW through the wafer boat 3, so that any abnormal electric discharge is not generated between the wafer boat 3 and the dummy wafers DW. In addition, as described above, if the source gas nozzle 52 is disposed in the second region S2 set by the relationship with the exhaust opening 20, the disturbance of gas flow is prevented as described above. Thus, the in-plane and inter-plane uniformities of film thickness can be improved, thereby performing a film forming process having satisfactory film forming performance.

In the above, the structure is disposed in a region having an electric field intensity of less than 8.12×10² V/m based on the power supplied to the electrode. This is because as described above, the region is a region capable of preventing the abnormal electric discharge from being generated. Although the electric field intensity distribution shown in FIGS. 7A and 7B is obtained by performing a simulation when the power applied to the first electrode 441 is 150 W, the result of the simulation is hardly changed even when the power is 200 W. Thus, if the region is a region having an electric field intensity of less than 8.12×10² V/m even when the power is 30 W to 200 W, it is possible to prevent the abnormal electric discharge from being generated. Even in a substrate processing apparatus for processing substrates other than the wafer having a diameter of 300 mm, if the structure is disposed in a region having an electric field intensity of less than 8.12×10² V/m based on the power supplied to the electrode, it is possible to prevent the abnormal electric discharge from being generated, thereby reducing particles.

In addition, when a plurality of source gas nozzles are used, all the source gas nozzles are disposed in the first region S1 described above, more preferably, the region in which the first and second regions S1 and S2 overlap each other. When a plurality of source gas nozzles are used as described above, the source gas nozzles, for example, are dividedly installed at the left and right sides with the plasma generating chamber 41 interposed therebetween. The position relationship between the exhaust opening 20 and the plasma generating chamber 41 is not limited to the example described above. For example, the exhaust opening 20 may be provided at a position opposite to the plasma generating chamber 41 with the wafer boat 3 interposed therebetween. In this case, the second region S2 is set with the exhaust opening 20 as a base point.

In addition, the electrode for generating plasma according to the present disclosure may be, for example, a coil-shaped electrode for generating inductively coupled plasma. In this case, for example, without installing the plasma generating chamber 41 protruding outward from the sidewall of the reaction chamber 1, a coil-shaped electrode obtained by forming a spiral-shaped coil in a planar shape may be installed onto the sidewall of the reaction chamber 1. The first region S1 is set with a portion closest to the structure as a base point. The structure of the present disclosure needs only to be installed in the reaction chamber 1 so as to extend in the length direction of the wafer boat 3 in the height region where the wafers W are arranged at a lateral side of the wafer boat 3 in the reaction chamber 1. The structure is not limited to the source gas nozzle 52 or the quartz pipe 72 supporting the thermocouple 71. Also, the structure may be a conductive or insulative body.

In addition to the dichlorosilane gas, the silane-based gas may include BTBAS ((bistertiarybutylamino)silane), HCD (hexadichlorosilane), 3DMAS (trisdimethylaminosilane), or the like. In addition to the nitrogen gas, an inert gas such as argon gas may be used as the replacement gas.

Further, in the substrate processing apparatus of the present disclosure, a titanium nitride (TiN) film may be formed using, for example, titanium chloride (TiCl₄) gas as the source gas and ammonia gas as the reaction gas. TMA (trimethylaluminum) may be used as the source gas.

The reaction for obtaining a desired film by reacting the source gas adsorbed onto the surface of the wafer W may include, for example, various reactions, such as oxidation reaction using O₂, O₃, H₂O or the like, reduction reaction using organic acid such as NH₃, H₂, HCOOH or CH₃COOH or alcohol such as CH₃OH or C₂H₅OH, carbonization reaction using CH₄, C₂H₆, C₂H₄, C₂H2 or the like, and nitriding reaction using NH₃, NH₂NH₂, N₂ or the like.

Three or four kinds of gases may be used as the source and reaction gases. As an example of using the three kinds of gases, a film may be formed using titanic acid strontium (SrTiO₃). For example, Sr(THD)₂ (strontium bis tetramethyl heptanedionate) that is a Sr source, Ti(OiPr)₂(THD)₂ (titanium bis isopropoxide bis tetramethyl heptanedionate) that is a Ti source, and ozone gas that is an oxidation gas thereof may be used. In this case, the gases are switched in the following order: Sr source gas→replacement gas→oxidation gas→replacement gas→Ti source gas→replacement gas→oxidation gas→replacement gas. When a plurality of source gas nozzles are used as described above, all the source gas nozzles are disposed in the first region S1 described above, more preferably, the region in which the first and second regions S1 and S2 overlap each other.

The film forming process of the present disclosure is not limited to the process in which a reaction product is stacked by a so-called ALD process, and may be applied to a substrate processing apparatus for performing a modification process on a substrate by activating a process gas composed of an inert gas using plasma.

### (Evaluation Test 1)

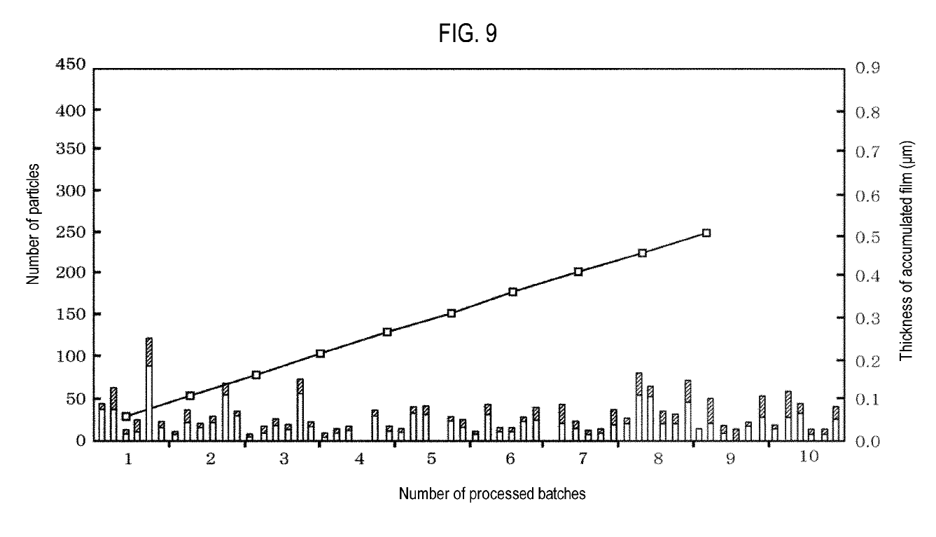

The film forming process of the SiN film described above was performed on the wafers W having the diameter of 300 mm through a plurality of batch processes, using the substrate processing apparatus described above, and the number and size of particles were then measured. At this time, the pressure in the reaction chamber 1 was set to 35.91 Pa (0.27 Torr), and the source gas nozzle 52 was disposed at a position where the linear distance to a portion closest to the first electrode 441 was 17 mm (a position where the angle θ2 made by the lines L1 and L6 shown in FIG. 5 was 50 degrees). The result is shown in FIG. 9. The horizontal axis represents the number of times the batch processes are performed, the left vertical axis represents the number of particles, and the right vertical axis represents a thickness of an accumulated film. The Number of particles in a specific slot of the wafer boat 3 is indicated by bar graphs, wherein particles having a size of less than 1 μm are indicated by white, and particles having a size of not less than 1 μm are indicated with a diagonal line. The thickness of an accumulated film on the dummy wafer DW is plotted by “□.”

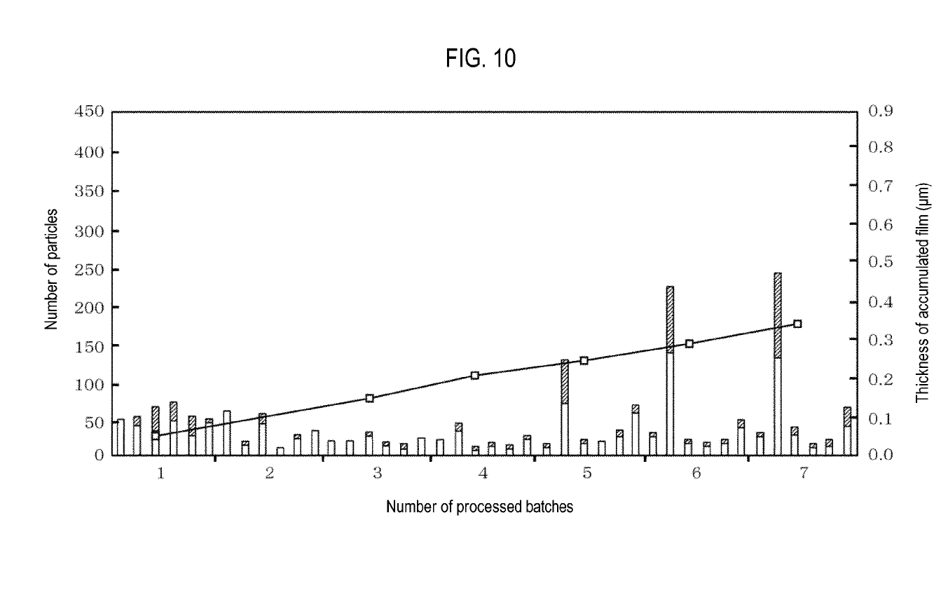

The same experiment was performed on the substrate processing apparatus in which the pressure in the reaction chamber 1 was set to 35.91 Pa (0.27 Torr), and the source gas nozzle 52 was disposed at a position where the linear distance to a portion closest to the first electrode 441 was 7 mm (a position where the angle θ2 made by the lines L1 and L6 shown in FIG. 5 was 25 degrees). The result is shown in FIG. 10.

As shown in FIGS. 9 and 10, when the source gas nozzle 52 was disposed in the first region S1 (θ2=50 degrees), the number of particles was sharply decreased as compared with when the source gas nozzle 52 was disposed in a region (e.g., θ2=25 degrees) other than the first region S1. From the result of FIG. 10, it was confirmed that a large quantity of particles are attached to the wafer W in a specific slot, regardless of the number of processed batches. From this point of view, if the source gas nozzle 52 is disposed in a region other than the first region S1, the abnormal electric discharge is generated between the dummy wafer DW and the source gas nozzle 52. The abnormal electric discharge damages a film accumulated on the dummy wafer DW, and the film is exfoliated into particles, which float. The particles may be attached to a wafer W in the vicinity of the dummy wafer DW. For this reason, it was confirmed that the prevention of the generation of the abnormal electric discharge between the structure and the dummy wafer DW by disposing the structure in the first region S1 is effective in reducing particles.

According to the present disclosure, a process gas is activated by supplying the process gas into the vertical reaction chamber having the vacuum atmosphere and supplying power to the process gas through the electrodes, thereby performing a process on substrates held in the shape of a shelf in the substrate holding unit. The structure installed in the reaction chamber to extend in the length direction of the substrate holding unit is disposed in a region spaced apart in the left or right direction from the electrode by not less than 40 degrees about the central portion of the reaction chamber when the reaction chamber is viewed from top. Since the region is a region having an electric field intensity of less than 8.12×10² V/m based on the power supplied to the electrode, the abnormal electric discharge generated through the structure is prevented, and the production of particles, which is a factor of the abnormal electric discharge, is prevented. As a result, it is possible to reduce particles attached to the substrates.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus for supplying a process gas to a plurality of substrates to perform a process on the plurality of substrates, which are semiconductor wafers having a diameter of 300 mm or more held in a substrate holding unit in a shape of a shelf in a vertical reaction chamber having a vacuum atmosphere, the apparatus comprising:
an electrode installed to extend in a length direction of the substrate holding unit to activate the process gas by supplying a power to the process gas;
a structure installed in the reaction chamber to extend in the length direction of the substrate holding unit in a height region where the plurality of substrates are arranged; and
an exhaust opening configured to vacuum exhaust an interior of the reaction chamber,
wherein the structure is disposed in a region spaced apart from a portion of the electrode closest to the structure by equal to or more than 40 degrees in a left or right direction about a central portion of the reaction chamber when the reaction chamber is viewed from top.

2. The apparatus of claim 1, wherein the structure is disposed in a region having an electric field intensity of less than 8.12×10² V/m based on the power supplied to the electrode.

3. A substrate processing apparatus for supplying a process gas to a plurality of substrates to perform a process on the plurality of substrates, which are held in a substrate holding unit in the shape of a shelf in a vertical reaction chamber having a vacuum atmosphere, the apparatus comprising:
an electrode installed to extend in a length direction of the substrate holding unit to activate the process gas by supplying a power to the process gas;
a structure installed in the reaction chamber to extend in the length direction of the substrate holding unit in a height region where the plurality of substrates are arranged; and
an exhaust opening configured to vacuum exhaust an interior of the reaction chamber,
wherein the structure is disposed in a region having an electric field intensity of less than 8.12×10² V/m based on the power supplied to the electrode.

4. The apparatus of claim 1, wherein a pressure in the reaction chamber is ranged from equal to or more than 6.65 Pa (0.05 Torr) to less than 66.5 Pa (0.5 Torr).

5. The apparatus of claim 1, wherein the power applied to the electrode is ranged from equal to or more than 30 W to less than 200 W.

6. The apparatus of claim 1, wherein the electrode is used to generate capacitively coupled plasma.

7. The apparatus of claim 1, further comprising:
a source gas nozzle installed to extend in an arrangement direction of the plurality of substrates in the reaction chamber, the source gas nozzle having a plurality of gas ejection holes along a length direction of the source gas nozzle to supply a source gas to the plurality of substrates for adsorption; and
a reaction gas nozzle installed to extend in the arrangement direction of the plurality of substrates in the reaction chamber, the reaction gas nozzle having a plurality of gas ejection holes along a length direction of the reaction gas nozzle, and alternately supplying a reaction gas reacting with the source gas and the source gas supply to stack a reaction product on the plurality of substrates,
wherein the reaction gas corresponds to a process gas, and the source gas nozzle corresponds to the structure.

8. The apparatus of claim 7, wherein a plasma generating chamber corresponds to a space surrounding a portion of a sidewall of the reaction chamber by a wall portion extending outward along the length direction of the substrate holding unit, and
wherein the electrode is a pair of opposing electrodes with the plasma generating chamber interposed between the pair of opposing electrodes.

9. The apparatus of claim 1, wherein the structure is a temperature detecting part configured to detect a temperature in the reaction chamber.

10. The apparatus of claim 7, wherein the exhaust opening is provided to vacuum exhaust the interior of the reaction chamber from a lateral side of the reaction chamber, and
wherein the source gas nozzle is installed at a position having an open angle ranged from equal to or more than 90 degrees to less than 160 degrees from a central portion in the left/right direction of the exhaust opening about a central portion of the reaction chamber when the reaction chamber is viewed from top.
